(19) United States
(12) Patent Application Publication
(10) Pub. No.: US 2002/0021727 A1
(43) Pub. Date: Feb. 21, 2002

(54) PASSIVATION LAYER FOR SEMICONDUCTOR LASER AND SEMICONDUCTOR LASER AND LASER MODULE USING THE SAME

(75) Inventors: NORIYUKI YOKOUCHI, YOKOHAMA-SHI (JP); MICHIO OHKUBO, FUJISAWA-SHI (JP)

Correspondence Address: FRISHAUF, HOLTZ, GOODMAN &, LANGER & CHICK, PC, 767 THIRD AVENUE, 25TH FLOOR, NEW YORK, NY, 10017-2023, US

(73) Assignee: THE FURUKAWA ELECTRIC CO., LTD., TOKYO (JP)

(21) Appl. No.: 09/210,350

(22) Filed: Dec. 11, 1998

(30) Foreign Application Priority Data
Dec. 15, 1997 (JP) 9-345407

(51) Int. Cl. H01S 5/00

(52) U.S. Cl. 372/49

(57) ABSTRACT

A passivation layer suppresses an output end face of a semiconductor laser having a band of an oscillation wavelength of 980 nm from being degraded and contributes to securance of the long-term reliability of the semiconductor laser. In a passivation layer, for a semiconductor laser, having a two-layered structure and constituted by a first thin film directly formed on the output end face of the semiconductor laser and a second thin film formed on a surface of the first thin film, the thickness of the first thin film is set such that, in a calculation expression for calculating the reflectance of the passivation layer by a matrix method, a differential coefficient obtained when the calculation expression is differentiated by the film thickness of the first thin film is zero.

### BACKGROUND OF THE INVENTION

1. Field of the Invention

The present invention relates to a passivation layer for a semiconductor laser, a semiconductor laser using the passivation layer, and a laser module in which the semiconductor device is incorporated and, more particularly, a passivation layer for a semiconductor laser having a structure in which an a resonator face of a semiconductor laser to form layer.

On the output face of the semiconductor laser described above, e.g., an InGaPa layer may be formed as a face protective film by an epitaxial crystal growing method on a cleavage surface exposed by cleaving the laminate structure of a semiconductor material. In this case, the passivation layer described above may be formed to cover the face protective film.

In recent years, a semiconductor laser having an oscillation wavelength being in a 980 -nm band has been energetically developed and studied. In a semiconductor laser of this type, when the passivation layer is constituted by a single film of AlOx, degradation of the output face rapidly advances. For this reason, the semiconductor laser stops actual operation within a short period of time.

In order to solve the above problems, in Japanese Unexamined Patent Publication No. 3-101183, it is proposed to constitute a passivation layer by a low-reflectance film having a two-layered structure. More specifically, an Si thin film having a film thickness of about 1 nm is directly formed on the output face of a semiconductor laser, and an SiNx thin film having a film thickness of about 140 nm is formed on the surface of the Si thin film. When this passivation layer is applied, the Si thin film suppresses oxygen from being diffused to the output face to prevent degradation of the output face. Therefore, long-term reliability of the semiconductor laser in operation is assured.

However, when the semiconductor laser having the passivation layer having the two-layered structure constituted by the Si thin film and the AlOx thin film is operated in a wavelength band of 980 nm, if an optical output on the output face becomes a high output of 200 mW or more, a phenomenon in which the temperature of the output face increases to considerably change an oscillation threshold current or an optical output with time occurs. After all, long-term operation reliability becomes poor.

### OBJECTS AND SUMMARY OF THE INVENTION

It is an object of the present invention to provide a passivation layer for making it possible to operate a semiconductor laser, which has a passivation layer having a two-layered structure and formed on an output face of the semiconductor layer, as a semiconductor laser having a small change in oscillation threshold current or a small change in optical output, therefore, having long-term reliability even if the semiconductor is kept operated for a long period of time.

It is another object of the present invention to provide a semiconductor laser having the passivation layer and a laser module in which the semiconductor laser is incorporated.

In order to achieve the above object, according to the present invention, there is provided a passivation layer for a semiconductor laser comprising:

a first thin film directly formed on an output face of the semiconductor laser; and a second thin film formed on a surface of the first thin film, wherein a film thickness of the first thin film is set such that, in a calculation expression for calculating a reflectance of the passivation layer as a whole by a matrix method, a differential coefficient obtained when the calculation expression is differentiated by the film thickness of the first thin film is zero.

There is also provided according to the present invention a passivation layer for a semiconductor laser, comprising: a first thin film directly formed on an output face of the semiconductor laser; and a second thin film formed on a surface of the first thin film, wherein the first thin film is a thin film of Si, the second thin film is a thin film of AlOₓ and the first thin film has a thickness of 15 to 25 μm.

According to the present invention, there is provided a semiconductor laser wherein the passivation layer is formed on an output face, and there is provided a laser module wherein the semiconductor laser is incorporated as a light source.

### BRIEF DESCRIPTION OF THE DRAWINGS

FIG. 1 is a sectional view showing a passivation layer having a two-layered structure; FIG. 2 is a graph obtained such that a calculation expression of a reflectance expressed by Equation (4) is plotted with a computer; and FIG. 3 is a graph obtained such that differences between reflectances of the passivation layer when the refractive index of the first thin film changes are plotted with a computer.

### DETAILED DESCRIPTION OF THE INVENTION

First, technical concepts of the present inventors who developed a passivation layer according to the present invention will be described below.

The present inventors had the following idea. That is, a reason for occurrence of a phenomenon in which an oscillation threshold current and an optical output considerably change when a semiconductor laser having a passivation layer having a two-layered structure is operated for a long period of time is based on the following technical matters.

More specifically, this phenomenon occurs when the output face is heated by heat generated by a high-output operation to transform the Si thin film directly formed on the output face. It is considered that, even if the transformed Si thin film has a film thickness which does not change from the film thickness obtained when the Si thin film is formed, the refractive index of the film changes. On the other hand, it is considered that the AlOx thin film formed on the surface of the Si thin film does not change in film thickness after and before the operation of the semiconductor laser, as a matter of course, and rarely change in refractive index.

The reflectance of a certain film with respect to light having a predetermined wavelength is a function of the refractive index of a material constituting the film and the film thickness. Therefore, the reflectance of the passivation layer having the two-layered structure is regulated by the film thickness and the refractive index of the Si thin film and the film thickness and the refractive index of the AlOx thin film.

Before and after the operation of the semiconductor laser, as described above, the AlOx thin film and the Si thin film may not change in film thickness, the AlOx thin film may not change in refractive index, and the Si thin film may change in only refractive index. For this reason, as a result, the change in reflectance of the passivation layer before and after the operation of the semiconductor laser may occur on the basis of the change in refractive index of the Si thin film.

Therefore, in order to suppress the change in reflectance of a passivation layer having a two-layered structure, it is preferable to prevent a film, e.g., an Si thin film, directly formed on an output face from changing in refractive index. However, since thermal transformation of the Si thin film inevitably occurs, it is actually impossible that the Si thin film is prevented from changing in refractive index.

Therefore, the present inventors had the following idea. That is, if the Si thin film is transformed to change its refractive index, when the film thickness of the Si thin film is set such that the change in refractive index affects the reflectance of the passivation layer, the passivation layer can be suppressed from changing in reflectance before and after an operation.

On the basis of the idea, a calculation expression by a matrix method (to be described later) of the reflectance of the passivation layer was analyzed , the film thickness of the Si thin film calculated by an arithmetic operation (to be described later) was set, and the relationship between the film thickness of the Si thin film and the change in reflectance in a passivation layer actually manufactured was examined. In this case, it could be confirmed that the above idea was right. On the basis of this confirmation, the passivation layer according to the present invention has been developed.

The above thinking process and the obtained effects will be exactly and concretely described below.

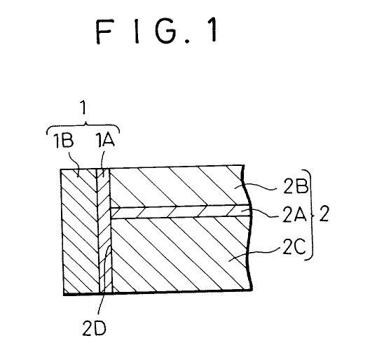

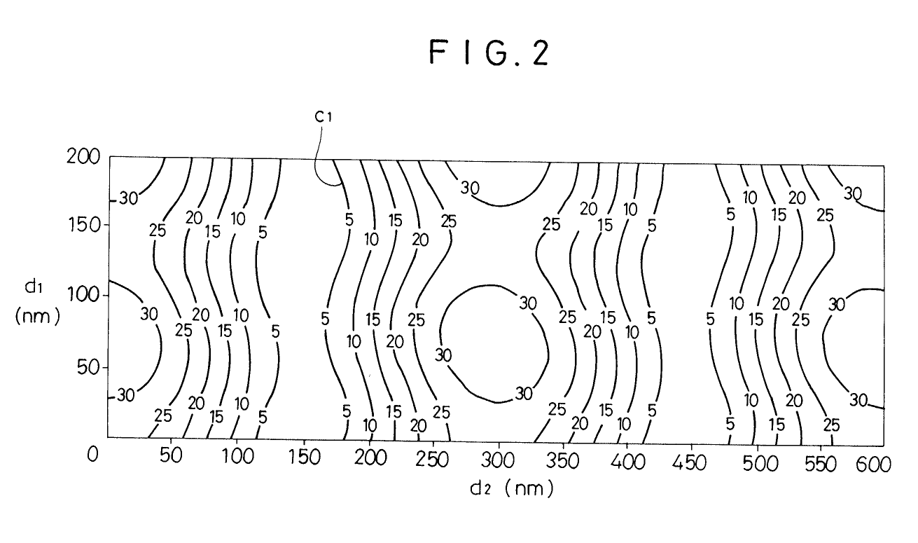

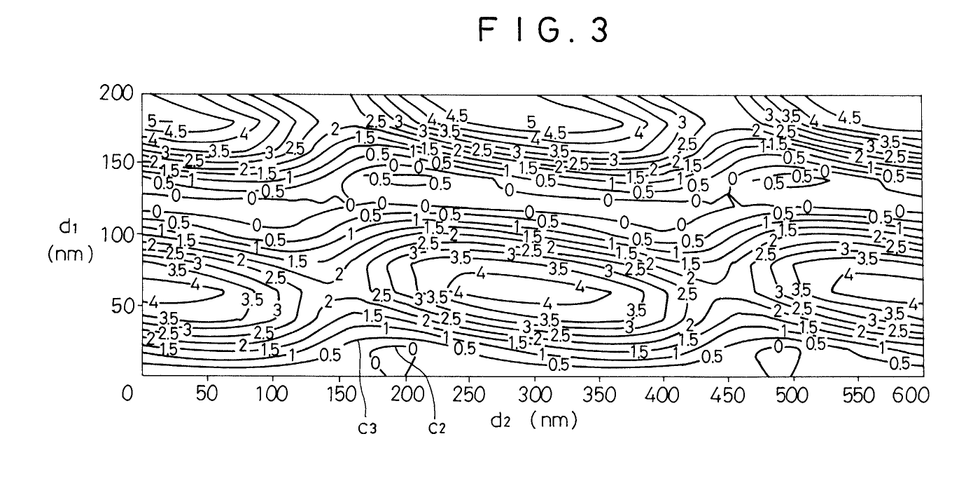

FIG. 1 is a sectional view showing a state in which a passivation layer having a two-layered structure is formed on an output face of a semiconductor laser.

Referring to FIG. 1, by using a predetermined semiconductor, an activation layer 2A is buried between a substrate 2C and a cladding layer 2B to form a semiconductor laser 2. On an output face 2D of the semiconductor laser 2, a first thin film 1A is formed to directly cover the output face 2D. A second thin film 1B is formed on the surface of the first thin film 1A, and a passivation layer 1 having a two-layered structure is formed as a whole.

Although the above-described face protective film on the output face 2D is not shown in FIG. 1, it is assumed that the present invention includes a case wherein a face protective film such as an InGaP layer may be formed on the output face 2D.

In this first thin film 1A, the first thin film 1A can consist of a material such as Si or TiO₂, and the second thin film 1B consists of a material such as AlOx, SiNx′, or SiO₂ different from the material of the first thin film. The reflectance and the film thickness of the passivation layer 1 is generally set such that about 5% of an optical output of a laser beam from the activation layer 2A can be reflected, and remaining about 95% of the optical output can be transmitted.

The passivation layer 1 of the present invention is characterized in that the film thickness of the first thin film 1A is determined as follows. This characteristic feature will be described below.

The refractive index of the semiconductor constituting the semiconductor laser 2 is represented by no, and the refractive index and the film thickness of the first thin film 1A are represented by n₁ and d₁, the refractive index and the film thickness of the second thin film 1B are represented by n₂ and d₂, and the refractive index of air is represented by 1.

Here, it is assumed that the wavelength of a laser beam (electromagnetic wave) from the output face 2D is represented by λ, when contribution of the electromagnetic wave to the electric field reflectance of the first thin film 1A is complexly expressed by a known matrix method, the contribution is given by the following expression:

$$( \begin{matrix}1 & 1 \\ {n}_{1} & - {n}_{1}\end{matrix} ) ( \begin{matrix}exp ( j \frac{2 π {n}_{1} {d}_{1}}{λ} ) & 0 \\ 0 & exp ( - j \frac{2 π {n}_{1} {d}_{1}}{λ} )\end{matrix} ) {( \begin{matrix}1 & 1 \\ {n}_{1} & - {n}_{1}\end{matrix} )}^{- 1} \qquad ( 1 )$$

Similarly, contribution to the electric field reflectance of the second thin film 1B is given by the following expression:

$$( \begin{matrix}1 & 1 \\ {n}_{2} & - {n}_{2}\end{matrix} ) ( \begin{matrix}exp ( j \frac{2 π {n}_{2} {d}_{2}}{λ} ) & 0 \\ 0 & exp ( - j \frac{2 π {n}_{2} {d}_{2}}{λ} )\end{matrix} ) {( \begin{matrix}1 & 1 \\ {n}_{2} & - {n}_{2}\end{matrix} )}^{- 1} \qquad ( 2 )$$

Therefore, according to the matrix method, an electric field reflectance S of the passivation layer 1 is given by the following equation:

$$\begin{matrix}S = {( \begin{matrix}1 & 1 \\ {n}_{0} & - {n}_{0}\end{matrix} )}^{- 1} ( \begin{matrix}1 & 1 \\ {n}_{1} & - {n}_{1}\end{matrix} ) \\ ( \begin{matrix}exp ( j \frac{2 π {n}_{1} {d}_{1}}{λ} ) & 0 \\ 0 & exp ( - j \frac{2 π {n}_{1} {d}_{1}}{λ} )\end{matrix} ) {( \begin{matrix}1 & 1 \\ {n}_{1} & - {n}_{1}\end{matrix} )}^{- 1} \\ ( \begin{matrix}1 & 1 \\ {n}_{2} & - {n}_{2}\end{matrix} ) ( \begin{matrix}exp ( j \frac{2 π {n}_{2} {d}_{2}}{λ} ) & 0 \\ 0 & exp ( - j \frac{2 π {n}_{2} {d}_{2}}{λ} )\end{matrix} ) \\ {( \begin{matrix}1 & 1 \\ {n}_{2} & - {n}_{2}\end{matrix} )}^{- 1} ( \begin{matrix}1 & 1 \\ 1 & - 1\end{matrix} )\end{matrix} \qquad ( 3 )$$

Here, when it is considered that a laser beam emitted from the second thin film 1B is not incident on the second thin film again, and a complex expression of the laser beam

$$exp ( j \frac{2 π nd}{λ} )$$

is converted into

$$cos \frac{2 π nd}{λ} + j s i n \frac{2 π nd}{λ} ,$$

the reflectance R of the passivation layer 1, a reflectance R of the passivation layer 1 is given by the following equation:

$$R = {\vert \frac{{S}_{10}}{{S}_{00}} \vert}^{2} \qquad ( 4 )$$

(where,

S₁₀=(−n₂·,n₁·n₀+n₂·n₁)cos(f₁)cos(f₂)+(n₂²·n₀−n₁²)sin(f₁)sin(f₂)+j{(n₂ ²·n₁−n₁·n₀)cos(f₁)sin(f₂)+(n₂·n₁²+n₂·n₀)sin(f₁)cos(f₂)}

S₀₀=(−n₂·n₁·n₀−n₂·n₁)cos(f₁)cos(f₂)+(n₂²·n₀+n₁²)sin(f₁)sin(f₂)+j{(−n₂² −n₁·n₀)cos(f₁)sin(f₂)+(−n₂·n₁²−n₂·n₀)sin(f₁)cos(f₂)}, f₁=2πn₁d₁/λ, and f₂=2πn₂d₂/λ).

Here, it is assumed that the first thin film consists of a material having a refractive index n₁=3.5, the second thin film consists of a material having a refractive index n₂=1.65, the wavelength of a laser beam is set to be 980 nm, and the semiconductor of the semiconductor laser consists of a material of a refractive index n₀=3.2. In this case, when a passivation layer is formed, a reflectance R(%), which is calculated from Equation (4), of the passivation layer when the film thickness d₁ of the first thin film and the film thickness d₂ of the second thin film are changed is plotted with a computer. The obtained result is shown in FIG. 2.

Contents signified by this graph will be described with reference to FIG. 2.

Each curve plotted in FIG. 2 is a curve indicating the reflectance R of Equation (4) calculated with a computer. For example, a curve c₁ in FIG. 2 indicates the relationship between d₁ and d₂ obtained, when d₁ and d₂ of a passivation layer to be formed are changed, when the reflectance R of the passivation layer has a 5% value.

As is apparent from FIG. 2, each of all the curves periodically has a point of inflection in the direction of the film thickness d₁. This is because Equation (4) is a trigonometric function.

At the point of inflection, if the film thickness d₁ changes, a change amount of the curve is smaller than at another point on the curve. More specifically, near the point of inflection, if the film thickness d, changes, the change in reflectance R of the passivation layer is small. In addition, the change in film thickness d₁ corresponds to a change in f₁ in Equation (4). It is considered that, if a change in refractive index n₁ is fine, the change in n₁ and the change in d₁ coincide with each other. Therefore, at this point of inflection, even if n₁ changes, a change in reflectance R may be small.

With reference to a curve c₁ in FIG. 2, for example, when the film thickness of the second thin film is set to be 180 nm, and the film thickness of the first thin film is set to be about 20 nm, this point is near the first point of inflection, and, at this time, the reflectance R of the passivation layer is 5%. At the same time, it is estimated that, even if the film thickness d₁ changes, a change rate of the reflectance R is almost zero.

The film thickness d₁ at which a change rate of the reflectance R of the passivation layer can be minimized is calculated as a value which makes a differential coefficient, which is obtained by differentiating Equation (4) serving as the calculation equation of the reflectance R by d₁, zero.

Therefore, Equation (4) is differentiated by d₁ to calculate

$$\frac{ⅆ R}{ⅆ {d}_{1}} .$$

As a result, the following equation can be obtained:

$$\begin{matrix}\frac{ⅆ R}{ⅆ {d}_{1}} = \frac{1}{{\vert d ( x ) \vert}^{4}} \cdot \frac{4 π {n}_{1}}{λ} \cdot \frac{1}{{cos}^{2} ( {f}_{1} )} \cdot \\ [ \begin{matrix}{\vert d ( x ) \vert}^{2} \{ AB + CD + ( {B}^{2} + {D}^{2} ) tan ( {f}_{1} ) \} \\ - {\vert f ( x ) \vert}^{2} \{ ab + cd + ( {b}^{2} + {d}^{2} ) tan ( {f}_{2} ) \}\end{matrix} ]\end{matrix} \qquad ( 5 )$$

(where,

A=(−n₂·n₁·n₀+n₂·n₁)cos(f₂),

B=(n₂²·n₀−n₁²)sin(f₂),

C=(n₂²·n₁ −n₁·n₀)sin(f ₂),

D=(n₂·n₁² −n₂n₀)cos(f₂),

a=(−n₂·n₁·n₀−n₂·n₁)cos(f₂),

b=(n₂²·n₀+n₁²)sin(f₂),

c=(−n₂²·n₁−n₁·n₀)sin(f₂),

d=(−n₂·n₁²−n₂n₀)cos(f₂),

|d(x)|²=(a²+c²)+2(ab+cd)tan(f₁)+(b²+d²)tan²(f₁),

and

|f(x)|²=(A²+C²)+2(AB+CD)tan(f₁)+(B²+D²)tan²(f₁).

Therefore, d₁ which satisfies

$$\frac{ⅆ R}{ⅆ {d}_{1}} = 0$$

0 is the target film thickness of the first thin film. The value may be obtained by calculating a d₁ value which makes the differential coefficient of Equation (5), i.e., the value in [] zero.

When the value in [] of Equation (5) is set to be zero, an obtained equation is a quadratic equation of tan(f₁), and tan(f₁) which is the solution to the quadratic equation is calculated as the following equation:

$$tan ( {f}_{1} ) = \frac{\begin{matrix}( β + γ \cdot {cos}^{2} ( {f}_{2} ) ) \pm \\ \sqrt{{( β + γ \cdot cos ( {f}_{2} ) )}^{2} + 43 {( α \cdot cos ( {f}_{2} ) sin ( {f}_{2} ) )}^{2}}\end{matrix}}{2 α cos ( {f}_{2} ) \cdot sin ( {f}_{2} )} \qquad ( 6 )$$

(where,

β=−n₂·n₁·(n₂−1)(n₂+1)(n₀−n₁)(n₀+n₁),

=−(n₁−n₂²)(n₁+n₂²)(n₀−n₁)(n₀+n₁), and

γ=−(n₂−1)(n₂+1) (n₂²+n₁²) (n₀−n₁) (n₀+n₁)).

Therefore, d₁ giving f₁ which satisfies Equation (6) is the solution of the target film thickness.

The approximate solution is given as the following expression:

$${d}_{1} \approx \frac{λ}{2 π {n}_{1}} ( - \frac{{n}_{2} {n}_{1} ( {n}_{2}^{2} - 1 ) cos ( {f}_{2} ) sin ( {f}_{2} )}{( {n}_{1}^{2} - {n}_{2}^{4} ) - ( {n}_{2}^{2} - 1 ) ( {n}_{2}^{2} + {n}_{1}^{2} ) {cos}^{2} ( {f}_{2} )} ) \qquad ( 7 )$$

According to Expression (7), the relationship of Equation (6) is satisfied. Therefore, the film thickness d₁ of the first thin film 1A which makes

$$\frac{ⅆ R}{ⅆ {d}_{1}} = 0$$

of Equation (5) zero and minimizes a change in reflectance expressed by Equation (4) is regulated by the refractive index (n₁) of a material constituting the first thin film 1A, the film thickness d₂ of the second thin film 1B, and the refractive index n₂ of a material constituting the second thin film 1B.

For this reason, according to the present invention, in formation of the passivation layer, materials constituting the first thin film and the second thin film are determined, and the film thickness d₂ of the second thin film is set to be a predetermined value. At this time, on the basis of Expression (7), the film thickness d, of the first thin film which can minimize a change rate of the reflectance R of the formed passivation layer can be calculated.

At this time, a plurality of approximates solutions d₁ are obtained in correspondence with points of inflection of the curves in FIG. 2. However, in general, the film thickness d₁ of the first thin film does not too large. Therefore, in fact, a minimum value of the calculated approximate solutions d₁ may be employed.

In Expression (7), the film thickness d₁ is also a function of the refractive index n₁. The refractive index n₁, as described above, changes during an operation of the semiconductor laser.

It is assumed that the first thin film corresponding to FIG. 2 is transformed to change the refractive index n₁ thereof from 3.5 to 3.7. The reflectances R₁ (n₁=3.5) and R₂ (n₁=3.7) expressed by Equation (4) in these cases are calculated with a computer, the difference: R₂−R₁between these values -is calculated, and the relationships between R₂—R₁, d₁, and d₂ are plotted. The result is shown in FIG. 3.

Contents signified by this graph will be described with reference to FIG. 3.

Curves plotted in FIG. 3 indicate R₂—R₁ calculated with a computer, i.e., a change in reflectance of the passivation layer caused by deformation of the first thin film. For example, a curve C₂ in FIG. 3 indicates the relationship between the film thickness d₁ and the film thickness d₂ which do not change when a change in reflectance of the formed passivation layer is zero even if the refractive index n, of the first thin film changes from 3.5 to 3.7. A curve c₃ located above the curve c₂indicates the relationship between the film thickness d₁ and the film thickness d₂ at which the change in reflectance is 0.5% even if the change in refractive index of the first thin film occurs.

With reference to the curve c₂ in FIG. 3, for example, the film thickness d₂ of the second thin film is set to be 180 nm, and the film thickness di of the first thin film is set to be about 20 nm. In this case, even if the material constituting the first thin film is transformed to considerably change the refractive index n₁, i.e., 0.2, the reflectance R of the formed passivation layer does not change.

In a semiconductor laser according to the present invention, the passivation layer described above is formed on the output face. For this reason, the output face is suppressed from being degraded even in a high-output operation, and the semiconductor laser achieves a high operation reliability for a long period of time.

In a laser module according to the present invention, the semiconductor laser is incorporated as a light source, and an optical fiber, a light-detector, a temperature control device, and the like are incorporated as auxiliary devices.

Examples

The passivation layer 1 shown in FIG. 1 was formed on the output face 2D of the semiconductor laser 2 which oscillates a laser beam having a 980-nm band to manufacture various samples. Here, the first thin film 1A was constituted by an α-Si film (n₁=3.5) having a film thickness d₁ described in Table 1, the second thin film 1B consisted of Al₂O₃ (n₂=1.65), and the film thickness d₂ of the second thin film 1B was set to be a predetermined value of about 180 nm. Under the above numeral conditions, di which made the differential coefficient of Equation (4) was calculated. As the d₁ value, 20 nm was obtained.

The α-Si thin film changes in film thickness. However, in any cases, the reflectance of the formed passivation layer 1 is set to be about 5%.

Variations in thickness of the thin films fall within the range of ±5 nm.

These semiconductor laser samples were energized at a temperature of 60° C. by a current of 350 mA for about 100 hours to be operated, and oscillation threshold currents and optical outputs obtained before and after the operation were measured to calculate the change rates of the oscillation threshold currents and the optical outputs. At the same time, the change rate of the reflectance of the passivation layer was also calculated on the basis of the measured values. These results are shown in Table 1.

TABLE 1

| | Film | | | |
|---|---|---|---|---|
| | Thickness | | | |
| | of α-Si | Change Rate of | Change Rate | Change Rate |
| | (d₁:nm) | Oscillation | of Optical | of |
| | Actual | Threshold | Output | Reflectance |
| | Thickness | Current (%) | (%) | (%) |
| Sample 1 | — | −0.3 | −0.1 | +0.1 |
| Sample 2 | 5 | +0.3 | +0.1 | −0.1 |
| Sample 3 | 10 | +1.0 | +0.3 | −0.3 |
| Sample 4 | 15 | +0.8 | +0.3 | −0.2 |
| Sample 5 | 20 | +0.3 | +0.1 | −0.1 |
| Sample 6 | 25 | −0.8 | −0.3 | +0.2 |
| Sample 7 | 30 | −2.1 | −0.6 | +0.5 |

The followings are apparent from Table 1.

(1) When the film thickness d, of the a-Si thin film is smaller than 30 nm, even after the 100-hour operation, the change rate of the oscillation threshold current and the change rate of the optical output are 1% or less and 0.5% or less as absolute values, respectively. The reflectance of the passivation layer is 0.3% or less as an absolute value.

(2) In particular, when the α-Si film is not formed, when d₁=5 nm, and when d₁=20 nm, low change rates are obtained.

However, when the α-Si film is not formed, or when d₁=5 nm oxide degradation of the output face may further advance in processes of a long-term operation to degrade the oscillation threshold value or the optical output. For this reason, in consideration of the operation reliability of the semiconductor laser, d₁=20 nm is preferably satisfied, more particularly, d₁ is preferably set to be 15 to 25 nm.

(3) To intermittently measure the film thickness d₁ of the α-Si thin film which decreases the change rate of the reflectance is a phenomenon corresponding to periodical calculation of points of inflection on the curve of the reflection shown in FIG. 2.

As is apparent from the above description, in the passivation layer of the present invention, the film thickness of the first thin film formed on the output face of the semiconductor laser is set such that the reflectance of the passivation layer as a whole does not change even if the refractive index of the first thin film changes. The change rate of the reflectance of the passivation layer can be reduced to 0.3% or less without degrading the long-term reliability of the semiconductor laser.

For this reason, the change rates of an oscillation threshold current before and after an operation of the semiconductor laser can be suppressed to 1% or less, and the change rate of an optical output can be suppressed to 0.5% or less.

Herein, (i) in all references to “AlOx”, x is from 1.0 to 2.5 and (ii) in all references to “SiNx′”, x′ is from 1.0 to 2.0.

What is claimed is:

1. A passivation layer for a semiconductor laser comprising:
a first thin film directly formed on an output face of said semiconductor laser; and a second thin film formed on a surface of said first thin film, wherein a film thickness of said first thin film is set such that, in a calculation expression for calculating a reflectance of said passivation layer as a whole by a matrix method, a differential coefficient obtained when the calculation expression is differentiated by the film thickness of said first thin film is zero.

2. A passivation layer for a semiconductor laser comprising:
a first thin film directly formed on an output face of the semiconductor laser; and a second thin film formed on a surface of the first thin film, wherein the first thin film is a thin film of Si, the second thin film is a thin film of AlOₓ wherein x is from 1 to 2.5, and the first thin film has a thickness of 15 to 25 μm.

3. A passivation layer for a semiconductor laser according to claim 1,
wherein said first thin film is a thin film consisting of Si, said second thin film is a thin film consisting of AlOₓ wherein x is from 1 to 2.5, and the film thickness of said first thin film is 15 to 25 nm.

4. A semiconductor laser
wherein said passivation layer according to claim 1 is formed on an output face.

5. A laser module
wherein said semiconductor laser according to claim 3 is incorporated as a light source.

6. A semiconductor laser
wherein said passivation layer according to claim 2 is formed on an output face.
